(19) United States
(12) Patent Application Publication
(10) Pub. No.: US 2009/0156008 A1
(43) Pub. Date: Jun. 18, 2009

(54) Polishing Composition and Polishing Method Using The Same

(75) Inventor: Kenji Sakamoto, Gifu-shi (JP)

Correspondence Address: VIDAS, ARRETT & STEINKRAUS, P.A., SUITE 400, 6640 SHADY OAK ROAD, EDEN PRAIRIE, MN, 55344, US

(73) Assignee: FUJIMI INCORPORATED, Kiyosu-shi (JP)

(21) Appl. No.: 12/371,840

(22) Filed: Feb. 16, 2009

Related U.S. Application Data
(62) Division of application No. 11/221,991, filed on Sep. 8, 2005.

(30) Foreign Application Priority Data
Sep. 9, 2004 (JP) 2004-262759

(51) Int. Cl. H01L 21/304; C09K 13/00

(52) U.S. Cl. 438/693; 252/79.1; 257/E21.23

(57) ABSTRACT

A polishing composition includes an abrasive, at least one compound of azoles and derivatives thereof, and water. The polishing composition is used in applications for polishing surfaces of semiconductor substrates in a suitable manner.

### BACKGROUND OF THE INVENTION

The present invention relates to a polishing composition for use in polishing surfaces of objects, such as semiconductor substrates, and to a method for polishing surfaces of objects, such as semiconductor substrates by using the polishing composition.

With respect to a polishing composition for use in polishing surfaces of semiconductor substrates, there have been strong demands for capability of polishing the substrate surfaces at a high removal rate and finishing them to have good surface qualities (in terms of surface roughness, haze, etc.), without causing metal contamination on the substrate surfaces. The polishing compositions disclosed in Japanese Laid-Open Patent Publications No. 63-272460 and No. 2001-77063 are compositions that have been improved so as to satisfy such demands. They, however, have not fully met these demands, still leaving room for improvement.

### SUMMARY OF THE INVENTION

Accordingly, the objective of the present invention is to provide a polishing composition that can be used more suitably in polishing a surface of a semiconductor substrate, and another objective of the present invention is to provide a method for polishing a surface of an object by using the polishing composition.

To achieve the foregoing and other objectives and in accordance with the purpose of the present invention, a polishing composition is provided. The polishing composition includes an abrasive, at least one compound selected from the group consisting of azoles and derivatives thereof, and water.

The present invention also provides a method for polishing a surface of an object. The method includes preparing the above polishing composition and polishing the surface of the object using the prepared polishing composition.

Other aspects and advantages of the invention will become apparent from the following description illustrating by way of example the principles of the invention.

### DETAILED DESCRIPTION OF THE PREFERRED EMBODIMENTS

An embodiment of the present invention will now be described. A polishing composition according to this embodiment contains an abrasive, a compound of azoles and derivatives thereof, and water.

The polishing composition is used in applications for polishing surfaces of semiconductor substrates such as silicon wafers. In other words, the polishing composition is used in applications for polishing surfaces of semiconductor substrates as semi-finished products to obtain semiconductor substrates as polished products. A surface of a semiconductor substrate is polished using the polishing composition, for example, by contacting a polishing member such as a polishing pad on the semiconductor substrate surface, and sliding either the semiconductor substrate or the polishing member while feeding the polishing composition into the contact portion.

The abrasive in the polishing composition plays the role of mechanically polishing semiconductor substrate surfaces to be polished. While an abrasive to be contained in the polishing composition may be any of silicon oxides, aluminum oxides, zirconium oxides, cerium oxides, and titanium oxides, the abrasive preferably contains silicon dioxide, and more preferably is silicon dioxide. Silicon dioxide is excellent in ability to polish semiconductor substrate surfaces. Silicon dioxide to be contained in the polishing composition may be any of fumed silica, colloidal silica, and precipitated silica, and preferably is fumed silica or colloidal silica, and more preferably is colloidal silica. Fumed silica and colloidal silica are superior to other silicon dioxides in their dispersion stability in water, and colloidal silica has less risk of causing defects such as scratches on semiconductor substrate surfaces to be polished.

An abrasive having too small an average particle size is not so high in ability to polish semiconductor substrate surfaces. Therefore, in view of accelerating polishing of semiconductor substrate surfaces with an abrasive, the average particle size of an abrasive to be contained in the polishing composition determined from the specific surface area of the abrasive measured by a BET method is preferably 0.001 μm or more, more preferably 0.01 μm or more. Meanwhile, when an abrasive has too large an average particle size, there is a risk of decreasing the stability of the polishing composition, causing the polishing composition to gelate or the abrasive to precipitate. Therefore, in view of inhibiting the stability of the polishing composition from decreasing, the average particle size of an abrasive to be contained in the polishing composition determined from the specific surface area of the abrasive measured by a BET method is preferably 1.0 μm or less, and more preferably 0.3 μm or less.

A polishing composition having too small an amount of an abrasive is not so high in polishing ability. Therefore, in view of further ensuring an improvement in polishing ability of the polishing composition, the content of the abrasive in the polishing composition is preferably 0.01% by mass or more, more preferably 0.1% by mass or more. Meanwhile, when the polishing composition contains a large amount of an abrasive, there is a risk that the viscosity of the polishing composition excessively increases. Therefore, in view of adequately controlling the viscosity of the polishing composition, the content of the abrasive in the polishing composition is 10% by mass or less, and more preferably 3% by mass or less.

The compound of azoles and derivatives thereof in the polishing composition contributes to the improvement of the polishing ability of the polishing composition. The reason why azoles and derivatives thereof can contribute to the improvement of the polishing ability is believed to be that an unshared electron pair of a nitrogen atom in a five-membered heterocyclic ring directly acts on the semiconductor substrate surfaces to be polished.

Azoles and derivatives thereof have less risk of causing metal contamination on semiconductor substrate surfaces to be polished unlike other amines such as monoethanolamine, 1,8-diazabicyclo(5,4,0)-undecene-7 (DBU for short), 1,5-diazabicyclo(4,3,0)-nonene-5 (DBN for short). The reason is believed to be that azoles and derivatives thereof are unlikely to coordinate with metal ions. In general, amines such as monoethanolamine coordinate with metal ions. Amines coordinated with metal ions are comparatively likely to dissociate. Thus, when a surface of a semiconductor substrate was polished using a polishing composition containing monoethanolamine, there is a risk that metal impurities in the polishing composition that have been bound to monoethanolamine exit from the monoethanolamine near the semiconductor substrate surface during polishing and are passed to the semiconductor substrate surface. Further, while DBU and DBN per se are unlikely to coordinate with metal ions, when they are hydrolyzed, they are converted to amines and coordinate with metal ions, leading to the risk of metal contamination on semiconductor substrate surfaces to be polished like amines such as monoethanolamine. Meanwhile, azoles and derivatives thereof are unlikely to coordinate with metal ions, nor are they hydrolyzed, and hence are believed to be unlikely to cause problems as in the case of monoethanolamine, DBU or DBN. The reason why azoles and derivatives thereof are unlikely to coordinate with metal ions is believed to be due to steric hindrance.

The azole derivatives may be those in which at least one of the hydrogen atoms bonded to a nitrogen atom or a carbon atom constituting a five-membered heterocyclic ring is substituted by an alkyl group such as a methyl group and an ethyl group; a hydroxyl group; a carboxyl group; or an amino group.

A compound of azoles and derivatives thereof to be contained in the polishing composition is preferably a compound of imidazole, triazoles, and their derivatives. When a compound of azoles and derivatives thereof to be contained in the polishing composition is a compound of imidazole, triazoles, and their derivatives, the risk of semiconductor substrate surfaces to be polished subjected to metal contamination is low.

The imidazole derivatives may be those in which at least one of the hydrogen atoms bonded to a nitrogen atom at the 1-position, to a carbon atom at the 2-position, to a carbon atom at the 4-position, and to a carbon atom at the 5-position of imidazole ring is substituted by an alkyl group such as a methyl group and an ethyl group; a hydroxyl group; a carboxyl group; or an amino group. The triazole derivatives may be those in which at least one of the hydrogen atoms bonded to a nitrogen atom at the 1-position, to a carbon atom at the 3-position, and to a carbon atom at the 5-position of triazole ring is substituted by an alkyl group such as a methyl group and an ethyl group; a hydroxyl group; a carboxyl group; or an amino group.

A polishing composition having too small an amount of a compound of azoles and derivatives thereof is not so high in polishing ability. Therefore, in view of further ensuring an improvement in polishing ability of the polishing composition, the content of the compound of azoles and derivatives thereof in the polishing composition is preferably 0.01% by mass or more, more preferably 0.1% by mass or more. Meanwhile, when the polishing composition contains a large amount of a compound of azoles and derivatives thereof, the chemical corrosion action of the polishing composition becomes too strong, and thus there is a risk of roughening the semiconductor substrate surfaces to be polished. Therefore, in view of inhibiting semiconductor substrate surfaces from roughening, the content of the compound of azoles and derivatives thereof in the polishing composition is preferably 10% by mass or less, and more preferably 3.0% by mass or less.

The water in the polishing composition serves as a medium for dispersing or dissolving components other than water in the polishing composition. Water to be contained in the polishing composition may be industrial water, tap water, distilled water, or one obtained by filtering any of these, and preferably contains as little impurities as possible.

This embodiment has the following advantages.

A polishing composition according to this embodiment contains a compound of azoles and derivatives thereof, which contributes to the improvement of polishing ability of the polishing composition. Thus, the polishing composition, compared to the conventional polishing compositions, has greater ability to polish surfaces of semiconductor substrates at a high removal rate. The polishing composition is hence useful in polishing surfaces of semiconductor substrates.

Azoles and derivatives thereof have less risk of metal contamination on surfaces of semiconductor substrates to be polished unlike other amines such as monoethanolamine, DBU and DBN. Thus, the degree of metal contamination on semiconductor substrate surfaces polished using a polishing composition according to this embodiment is less than that on semiconductor substrate surfaces polished using a polishing composition containing monoethanolamine, DBU and DBN. When a semiconductor device is produced using a metal-contaminated semiconductor substrate, there is a risk of decreasing the electric characteristics of the semiconductor. Meanwhile, according to this embodiment, semiconductor substrates in which the reduction in the degree of metal contamination is controlled are provided, and therefore semiconductor devices in which the reduction of electric characteristics is controlled are provided.

If an oxidizing agent is contained in a polishing composition according to this embodiment, there is a risk that oxide passive layers will be formed on surfaces of semiconductor substrates to be polished during polishing depending on the amount of an oxidizing agent to be contained. When oxide passive layers are formed on semiconductor substrate surfaces, there is a risk of inhibiting the chemical polishing of the semiconductor substrate surfaces. Since a polishing composition according to this embodiment contains no oxidizing agents, it can avoid such problems attributable to an oxidizing agent.

The above-described embodiment may be modified in the following manner.

A polishing composition according to the above-described embodiment may further contain a polishing accelerator. A polishing accelerator plays the role of chemically polishing semiconductor substrate surfaces to be polished and contributes to the improvement of polishing ability of the polishing composition. While a polishing accelerator to be contained in the polishing composition may be any of alkali metal hydroxides, alkali metal salts, ammonium hydroxides, and ammonium salts, the accelerator preferably contains any of lithium hydroxide, sodium hydroxide, potassium hydroxide, potassium carbonate, potassium hydrogencarbonate, sodium carbonate, sodium hydrogencarbonate, ammonium hydroxide, ammonium carbonate, quaternary ammonium salts, and quaternary ammonium hydroxides, and more preferably contains any of sodium hydroxide, potassium hydroxide, or tetramethylammonium hydroxide. Lithium hydroxide, sodium hydroxide, potassium hydroxide, potassium carbonate, potassium hydrogencarbonate, sodium carbonate, sodium hydrogencarbonate, ammonium hydroxide, ammonium carbonate, quaternary ammonium salts, and quaternary ammonium hydroxides are high in ability to chemically polish semiconductor substrate surfaces. Sodium hydroxide, potassium hydroxide and tetramethylammonium hydroxide are particularly high in ability to chemically polish semiconductor substrate surfaces.

When the polishing composition contains only a small amount of a polishing accelerator, polishing ability of the polishing composition cannot be improved enough. Therefore, in view of greatly improving polishing ability of the polishing composition, the content of the polishing accelerator in the polishing composition is preferably 0.001% by mass or more, more preferably 0.1% by mass or more when the polishing accelerator is alkali metal hydroxide or alkali metal salt; or 0.05% by mass or more when the polishing accelerator is ammonium hydroxide or ammonium salt. Meanwhile, when the polishing composition contains a large amount of a polishing accelerator, the chemical corrosion action of the polishing composition becomes too strong, and thus there is a risk of roughening semiconductor substrate surfaces to be polished. Therefore, in view of inhibiting semiconductor substrate surfaces from roughening, the content of the polishing accelerator in the polishing composition is preferably 20% by mass or less, more preferably 1.0% by mass or less when the polishing accelerator is alkali metal hydroxide or alkali metal salt; or 2.0% by mass or less when the polishing accelerator is ammonium hydroxide or ammonium salt.

A polishing composition according to the above-described embodiment may further contain a chelating agent, which inhibits contamination of semiconductor substrate surfaces to be polished by metal impurities by capturing metal impurities by forming a complex ion with them in the polishing composition.

Preferred are chelating agents that can effectively capture iron, nickel, copper, calcium, chromium, and zinc. Examples of such chelating agents include aminocarboxylic acid base chelating agents or phosphonic acid base chelating agents, more specifically, ethylenediaminetetraacetic acid, diethylenetriaminepentaacetic acid, triethylenetetraminehexaacetic acid, ethylenediaminetetra(methylenephosphonic acid), and diethylenetriaminepenta(methylenephosphonic acid).

When the polishing composition contains only a small amount of a chelating agent, metal contamination of semiconductor substrate surfaces to be polished cannot be substantially inhibited. Therefore, in view of strongly inhibiting metal contamination, the content of the chelating agent in the polishing composition is preferably 0.001% by mass or more, more preferably 0.01% by mass or more. Meanwhile, a polishing composition containing a large amount of a chelating agent tends to gelate. Therefore, in view of preventing gelation, the content of the chelating agent in the polishing composition is preferably 0.2% by mass or less, more preferably 0.1% by mass or less.

The polishing composition according to the above-described embodiment may further contain a water-soluble polymer. A water-soluble polymer acts so as to improve wettability of semiconductor substrate surfaces to be polished. In the case of semiconductor substrate surfaces having a high wettability, even if an abrasive adheres to the semiconductor substrate surfaces, the abrasive can be easily removed therefrom by simple washing. A water-soluble polymer to be contained in the polishing composition preferably contains at least one compound selected from the group consisting of hydroxyethyl cellulose, polyvinyl alcohol, polyethylene oxide and polyethylene glycol, and more preferably contains hydroxyethyl cellulose. Hydroxyethyl cellulose, polyvinyl alcohol, polyethylene oxide and polyethylene glycol are high in ability to improve wettability of semiconductor substrate surfaces to be polished, and hydroxyethyl cellulose is particularly high in ability to improve wettability of semiconductor substrate surfaces to be polished.

When the molecular weight of a water-soluble polymer to be contained in the polishing composition is too low, there is a risk that the haze value of semiconductor substrate surfaces to be polished increases. Therefore, in view of controlling the haze value to a low value, the molecular weight of hydroxyethyl cellulose to be contained in the polishing composition is preferably 300,000 or more, more preferably 600,000 or more; the molecular weight of polyvinyl alcohol to be contained in the polishing composition is preferably 1,000 or more, more preferably 5,000 or more; the molecular weight of polyethylene oxide to be contained in the polishing composition is preferably 20,000 or more; and the molecular weight of polyethylene glycol to be contained in the polishing composition is preferably 100 or more, more preferably 300 or more. Meanwhile, when the molecular weight of a water-soluble polymer to be contained in the polishing composition is too high, there is a risk that the viscosity of the polishing composition excessively increases. Therefore, in view of adequately controlling the viscosity of the polishing composition, the molecular weight of hydroxyethyl cellulose to be contained in the polishing composition is preferably 3,000,000 or less, more preferably 2,000,000 or less; the molecular weight of polyvinyl alcohol to be contained in the polishing composition is preferably 1,000,000 or less, more preferably 500,000 or less; the molecular weight of polyethylene oxide to be contained in the polishing composition is preferably 50,000,000 or less, more preferably 30,000,000 or less; and the molecular weight of polyethylene glycol to be contained in the polishing composition is preferably 20,000 or less.

When the polishing composition contains only a small amount of a water-soluble polymer, the wettability of semiconductor substrate surfaces to be polished cannot be substantially improved. Therefore, in view of greatly improving the wettability, the content of the water-soluble polymer in the polishing composition is preferably 0.0001% by mass or more, more preferably 0.001% by mass or more, most preferably 0.005% by mass or more. Meanwhile, when the polishing composition contains a large amount of a water-soluble polymer, there is a risk that the viscosity of the polishing composition excessively increases. Therefore, in view of adequately controlling the viscosity of the polishing composition, the content of the water-soluble polymer in the polishing composition is preferably 0.5% by mass or less, more preferably 0.3% by mass or less, most preferably 0.15% by mass or less.

A polishing composition according to the above-described embodiment may further contain a small amount of an oxidizing agent. When the polishing composition contains a large amount of an oxidizing agent (for example, the case where the content of the oxidizing agent in the polishing composition is 1.2% by mass or more), there is a risk of reducing polishing ability of the polishing composition since, as described above, oxide passive layers are formed on surfaces of semiconductor substrates to be polished. When the content of the oxidizing agent is small, no oxide passive layers are formed, or only extremely thin passive layers are formed, which could be easily removed by the mechanical polishing action of the abrasive. Therefore, in view of preventing polishing ability of the polishing composition from decreasing, the content of the oxidizing agent in the polishing composition is preferably 0.1% by mass or less, more preferably 0.01% by mass or less.

A polishing composition according to the above-described embodiment may contain both one or more compounds of azoles and one or more compounds of azole derivatives.

A polishing composition according to the above-described embodiment may be prepared by diluting with water an undiluted polishing composition.

A polishing composition according to the above-described embodiment may be used in applications for polishing a surface of an object other than semiconductor substrates.

The present invention will be described in more detail by referring to Examples and Comparative Examples.

In Examples 1 to 18, an abrasive, a compound of azoles and derivatives thereof, and water were mixed, and to the mixture was further added, if necessary, a polishing accelerator or a chelating agent to prepare undiluted polishing compositions. In Comparative Examples 1 to 8, an abrasive and water were mixed, and to the mixture was further added, if necessary, a compound of azoles, azole derivatives and their replacements, a polishing accelerator, or a chelating agent to prepare undiluted polishing compositions. The undiluted polishing compositions of Examples 1 to 18 and Comparative Examples 1 to 8 were diluted with water 15-fold in volume ratio to prepare polishing compositions of Examples 1 to 18 and Comparative Examples 1 to 8. The details for abrasives, compounds of azoles and derivatives thereof, polishing accelerators, and chelating agents used in Examples 1 to 18 are shown in Table 1. The details for abrasives, compounds of azoles, azole derivatives and their replacements, polishing accelerators, and chelating agents used in Comparative Examples 1 to 8 are shown in Table 2.

The surface of a silicon wafer was polished using each polishing composition of Examples 1 to 18 and Comparative Examples 1 to 8 under the following polishing conditions.

### Polishing Conditions

Polishing machine: Single-sided polishing machine “SPM-15” manufactured by Fujikoshi Machinery Corp.
Polishing pressure: 31.5 kPa
Platen rotation speed: 58 rpm
Polishing time: 15 minutes
Polishing pad: “MH-S15A” manufactured by Rodel
Polishing load: 2226 N (=227 kgf)
Inner load: 100 kPa (wafer surface pressure 31 kPa (=320 g/cm²))
Feed rate of platen cooling water: 16 L/minute
Temperature of platen cooling water: 20° C.
Feed rate of polishing composition: 8.0 L/minute
Feed amount of polishing composition: 30 L
Temperature of polishing composition: 25° C.

The thickness of each silicon wafer was measured by a dial gauge before and after polishing under the above-described polishing conditions, and the reduction in thickness of each wafer due to polishing was obtained. Polishing rate (stock removal rate) obtained by dividing the reduction in thickness of each wafer by polishing time for each polishing composition is shown in the column entitled “Polishing rate” in Tables 1 and 2.

The surface roughness Ra of each polished silicon wafer was measured by a surface roughness measuring machine “RST Plus” manufactured by WYKO with a measuring magnification of 5 (object lens magnification 10× multiple-magnification lens magnification 0.5). The results are shown in the column entitled “Surface roughness Ra” in Tables 1 and 2.

After heating polished silicon wafers for one hour at 200° C., metal impurities in the wafers were quantitatively analyzed by vapor phase decomposition-inductively coupled plasma mass spectrometry (VPD-ICP-MS). The results are shown in the column entitled “Metal contamination” in Tables 1 and 2.

Silicon wafers used in determining polishing rate and surface roughness Ra were those with a specific resistance of 0.1 Ω·cm or more, and silicon wafers used in evaluating metal contamination were those with a specific resistance of less than 0.01 Ω·cm.

TABLE 1

| | | Compound of azoles and | Polishing | | | Surface | |
|---|---|---|---|---|---|---|---|
| | Abrasive | derivatives thereof | accelerator | Chelating agent | Polishing rate | roughness Ra | Metal contamination |
| | [mass percentage] | [mass percentage] | [mass percentage] | [mass percentage] | [μm/minute] | [nm] | [×10¹⁰ atoms/cm²] |
| Ex. 1 | colloidal silica*¹ | imidazole | — | — | 0.7 | 0.4 | 19 |
| | 1.2% | 1.2% | | | | | |
| Ex. 2 | colloidal silica*¹ | 2-methylimidazole | — | — | 0.7 | 0.4 | 19 |
| | 1.2% | 1.2% | | | | | |
| Ex. 3 | colloidal silica*¹ | 3-amino-1,2,4-triazole | — | — | 0.6 | 0.4 | 18 |
| | 1.2% | 1.2% | | | | | |
| Ex. 4 | colloidal silica*¹ | imidazole | — | — | 0.8 | 0.4 | 20 |
| | 1.2% | 4.8% | | | | | |
| Ex. 5 | colloidal silica*¹ | imidazole | TMAH | — | 1.0 | 0.7 | 19 |
| | 1.2% | 1.2% | 4.3% | | | | |
| Ex. 6 | colloidal silica*¹ | imidazole | — | TTHA | 0.8 | 0.4 | 8.6 |
| | 1.2% | 1.2% | | 0.018% | | | |
| Ex. 7 | colloidal silica*¹ | imidazole | TMAH | TTHA | 1.0 | 0.7 | 8.6 |
| | 1.2% | 1.2% | 4.3% | 0.018% | | | |
| Ex. 8 | colloidal silica*¹ | imidazole | TMAH | TTHA | 1.0 | 0.7 | 8.6 |
| | 1.2% | 3.4% | 4.3% | 0.018% | | | |
| Ex. 9 | colloidal silica*¹ | imidazole | TMAH | TTHA | 1.0 | 0.7 | 8.6 |
| | 1.2% | 4.8% | 4.3% | 0.018% | | | |
| Ex. 10 | colloidal silica*¹ | imidazole | TMAH | TTHA | 1.1 | 0.7 | 8.6 |
| | 1.2% | 6.0% | 4.3% | 0.018% | | | |
| Ex. 11 | colloidal silica*¹ | imidazole | KOH | TTHA | 1.0 | 0.5 | 8.6 |
| | 1.2% | 1.2% | 1.8% | 0.018% | | | |
| Ex. 12 | colloidal silica*¹ | imidazole | NaOH | TTHA | 1.0 | 0.5 | 8.6 |
| | 1.2% | 1.2% | 4.3% | 0.018% | | | |
| Ex. 13 | colloidal silica*¹ | imidazole | NH₄OH | TTHA | 1.0 | 0.5 | 8.6 |
| | 1.2% | 1.2% | 4.3% | 0.018% | | | |
| Ex. 14 | colloidal silica*² | imidazole | TMAH | TTHA | 1.0 | 0.7 | 8.6 |
| | 1.2% | 1.2% | 4.3% | 0.018% | | | |
| Ex. 15 | colloidal silica*³ | imidazole | TMAH | TTHA | 1.0 | 0.7 | 8.6 |
| | 1.2% | 1.2% | 4.3% | 0.018% | | | |
| Ex. 16 | colloidal silica*¹ | imidazole | TMAH | EDTA | 1.0 | 0.7 | 8.6 |
| | 1.2% | 1.2% | 4.3% | 0.018% | | | |
| Ex. 17 | colloidal silica*¹ | imidazole | TMAH | DTPA | 1.0 | 0.7 | 8.6 |
| | 1.2% | 1.2% | 4.3% | 0.018% | | | |
| Ex. 18 | colloidal silica*¹ | imidazole | TMAH | EDTPO | 1.0 | 0.7 | 8.6 |
| | 1.2% | 1.2% | 4.3% | 0.018% | | | |

TABLE 2

| | | Compound of azoles, | | | | | |
|---|---|---|---|---|---|---|---|
| | | azole derivatives and | | | | Surface | |
| | Abrasive | their replacements | Polishing accelerator | Chelating agent | Polishing rate | roughness Ra | Metal contamination |
| | [mass percentage] | [mass percentage] | [mass percentage] | [mass percentage] | [μm/minute] | [nm] | [× 10¹⁰ atoms/cm²] |
| C. Ex. 1 | colloidal silica*¹ | — | KOH | — | 0.5 | 0.6 | 21 |
| | 1.2% | | 1.8% | | | | |
| C. Ex. 2 | colloidal silica*¹ | — | TMAH | — | 0.7 | 0.9 | 21 |
| | 1.2% | | 4.3% | | | | |
| C. Ex. 3 | colloidal silica*¹ | monoethanolamine | — | TTHA | 1.1 | 1.1 | 1100 |
| | 1.2% | 0.67% | | 0.018% | | | |
| C. Ex. 4 | colloidal silica*¹ | monoethanolamine | TMAH | TTHA | 1.1 | 1.1 | 1000 |
| | 1.2% | 0.67% | 4.3% | 0.018% | | | |
| C. Ex. 5 | colloidal silica*¹ | DBN | — | TTHA | 0.7 | 0.7 | 50 |
| | 1.2% | 0.35% | | 0.018% | | | |
| C. Ex. 6 | colloidal silica*¹ | DBU | — | TTHA | 0.7 | 0.7 | 52 |
| | 1.2% | 0.35% | | 0.018% | | | |
| C. Ex. 7 | colloidal silica*¹ | DBN | — | TTHA | 1.0 | 0.7 | 800 |
| | 1.2% | 1.7% | | 0.018% | | | |
| C. Ex. 8 | colloidal silica*¹ | DBU | — | TTHA | 0.7 | 0.7 | 2100 |
| | 1.2% | 1.7% | | 0.018% | | | |

In the column entitled “Abrasive” in Tables 1 and 2, “Colloidal silica*¹” denotes colloidal silica with an average particle size of 55 nm; “Colloidal silica*²” denotes colloidal silica with an average particle size of 9.5 nm; and “Colloidal silica*³” denotes colloidal silica with an average particle size of 90 nm. These average particle sizes were determined from a specific surface area measured by a BET method. In the column entitled “Polishing accelerator” in Tables 1 and 2, “KOH” represents potassium hydroxide, “TMAH” represents tetramethylammonium hydroxide, “NaOH” represents sodium hydroxide, and “NH₄OH” represents ammonium hydroxide. In the column entitled “Chelating agent” in Tables 1 and 2, “TTHA” represents triethylenetetraminehexaacetic acid, “EDTA” represents ethylenediaminetetraacetic acid, “DTPA” represents diethylenetriaminepentaacetic acid, and “EDTPO” represents ethylenediaminetetra(methylenephosphonic acid).

What the results in Tables 1 and 2 indicate is summarized below.

The polishing rate determined using the polishing composition of Example 5 is greater than the polishing rate determined using the polishing composition of Comparative Example 2. The results suggest that polishing ability of the polishing composition is improved by the addition of a compound of azoles and derivatives thereof.

The degree of metal contamination on silicon wafers determined using the polishing compositions of Examples 1 to 18 is less than the degree of metal contamination on silicon wafers determined using the polishing compositions of Comparative Examples 3 to 8 containing monoethanolamine, DBU, or DBN. The results suggest that azoles and derivatives thereof cause less metal contamination on silicon wafers than monoethanolamine, DBU, or DBN.

The degree of metal contamination on silicon wafers determined using the polishing compositions of Examples 6 to 18 containing a chelating agent is less than the degree of metal contamination on silicon wafers determined using the polishing compositions of Examples 1 to 5 containing no chelating agents. The results suggest that metal contamination on silicon wafers can be inhibited by the addition of a chelating agent.

The surface roughness of silicon wafers determined using the polishing compositions of Examples 1 to 4 and 6 containing no polishing accelerators is less than the surface roughness of silicon wafers determined using the polishing compositions of Examples 5 and 7 to 18 and Comparative Examples 1 and 2 containing a polishing accelerator. The surface roughness of silicon wafers determined using the polishing compositions of Example 4 containing a large amount of imidazole is almost equivalent to the surface roughness of silicon wafers determined using the polishing composition of Example 1 containing a small amount of imidazole. These results suggest that there is a risk of roughening wafer surfaces by the addition of a polishing accelerator, and that there is little risk of roughening wafer surfaces even by increasing the content of a compound of azoles and derivatives thereof.

1. A polishing composition comprising:
an abrasive;
at least one compound selected from the group consisting of azoles and derivatives thereof; and
water.

2. The polishing composition according to claim 1, wherein the at least one compound is selected from the group consisting of imidazole, triazoles, and their derivatives.

3. The polishing composition according to claim 1, further comprising a polishing accelerator.

4. The polishing composition according to claim 1, further comprising a chelating agent.

5. The polishing composition according to claim 1, further comprising a water-soluble polymer.

6. The polishing composition according to claim 1, wherein the polishing composition substantially contains no oxidizing agents.

7. The polishing composition according to claim 1, further comprising an oxidizing agent, wherein the content of the oxidizing agent in the polishing composition is 0.1% by mass or less.

8. The polishing composition according to claim 1, wherein the polishing composition is used for polishing a surface of a semiconductor substrate.

9. A method for polishing a surface of an object, the method comprising:
preparing a polishing composition including an abrasive, at least one compound selected from the group consisting of azoles and derivatives thereof, and water; and
polishing the surface of the object using the prepared polishing composition.

10. The method according to claim 9, wherein the object is a semiconductor substrate.
